(19) United States
(12) Patent Application Publication
(10) Pub. No.: US 2017/0126224 A1
(43) Pub. Date: May 4, 2017

(54) HIGH SIDE POWER DEVICE GATE DRIVER

(71) Applicant: Eaton Corporation, Cleveland, OH (US)

(72) Inventors: Stan Lawrence Seely, Byron Center, MI (US); Sayeed Ahmed Mir, Saginaw, MI (US)

(21) Appl. No.: 15/335,929

(22) Filed: Oct. 27, 2016

Related U.S. Application Data
(60) Provisional application No. 62/248,388, filed on Oct. 30, 2015.

(51) Int. Cl. H03K 17/567; H03K 17/081; H02P 27/08; H03K 17/687; H02M 1/32; H02M 7/5395

(52) U.S. Cl. CPC H03K 17/567; H02M 1/32; H02M 7/5395; H02P 27/08; H03K 17/687; H03K 17/08104; H03K 17/08116

(57) ABSTRACT

A system comprises a power device, a gate driver integrated circuit and an isolated voltage supply. The power device has a gate and is configured to turn on in response to a control voltage applied at the gate. The gate driver integrated circuit is electrically coupled to the gate and is configured to supply the control voltage without the use of a bootstrap circuit. The isolated voltage supply comprises a negative voltage supply that is electrically coupled to the gate of the power device.

### CROSS REFERENCE TO RELATED APPLICATION

This application claims the benefit of provisional application Ser. No. 62/248,388, filed Oct. 30, 2015, which is incorporated herein by reference in its entirety.

### FIELD OF THE DISCLOSURE

The present disclosure generally relates to a gate driver of a power device and, more particularly, to a gate driver configuration incorporating the use of a positive and a negative isolated voltage supply.

### BACKGROUND OF THE DISCLOSURE

Inverter bridge circuits for powering electric motors make use of gate driver circuitry to control individual power devices, e.g., IGBTs (insulated gate bipolar transistor) and MOSFETs (metal-oxide semiconductor field-effect transistor). Inverter systems involving higher voltages require that the gate driver circuit be isolated. Several commercially available integrated circuit (IC) manufacturers offer high voltage isolation without explicit negative power supply support for the gate of the interfaced power device. These commercially available ICs use a method of bootstrapping for high voltage operation while interfacing to low voltage systems. For example, a typical gate driver circuit topology for a three-phase power inverter connected to an electrical motor commonly uses a bootstrapping capacitor charging technique as a means to control a power device. Typically these commercially available ICs offer integrated desirable features such as supply under voltage protection and over-current/desaturation protection. However, the commercially available ICs fail to offer high voltage isolation with explicit negative power supply support for the gate of the interfaced power device.

### SUMMARY

One aspect of the present disclosure is directed to a system comprising a power device, a gate driver integrated circuit and an isolated voltage supply. The power device has a gate and is configured to turn on in response to a control voltage applied at the gate. The gate driver integrated circuit is electrically coupled to the gate and is configured to supply the control voltage without the use of a bootstrap circuit. The isolated voltage supply comprises a negative voltage supply that is electrically coupled to the gate of the power device.

Another aspect of the present disclosure is directed to a three-phase power inverter. The inverter has three high side power device and three low side power devices. Each high side power device is coupled to a respective low side power device in a half bridge configuration. Each high side power device is coupled to a gate driver integrated circuit where the gate driver integrated circuit is referenced to a negative voltage, rather than to ground. The negative voltage is provided by an isolated negative voltage supply. The gate driver integrated circuit is configured to produce a control voltage sufficient to turn on the power device without the use of a bootstrap circuit.

Still another aspect of the invention is directed to a method. The method comprises: (1) charging a capacitor with an isolated high voltage, positive voltage supply to generate a first voltage; (2) providing the first voltage to a gate driver integrated circuit that is referenced to a negative voltage supplied by an isolated negative voltage supply; (3) using the gate driver integrated circuit to generate a control voltage from the first voltage; and (4) applying the control voltage to a gate of a power device to turn on the power device.

The above summary is not intended to describe each embodiment or every implementation. A more complete understanding will become apparent and appreciated by referring to the following detailed description and claims in conjunction with the accompanying drawings.

### DESCRIPTION OF THE DRAWINGS

FIG. 1 is schematic of a traditionally configured gate driver arrangement for a three-phase inverter.

FIG. 2 is a schematic of a gate driver for a high side power device as illustrated in FIG. 1.

FIG. 3 is a schematic of a negative supply capable, isolated gate driver arrangement for a three-phase inverter in accordance with various embodiments of the present disclosure.

FIG. 4 is a schematic of a gate driver for a high side power device as illustrated in FIG. 3 and in accordance with various embodiment of the present disclosure.

FIG. 5 is a schematic of a gate driver for a high side power device as illustrated in FIG. 3 and in accordance with various embodiments of the present disclosure.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The present disclosure is directed to a gate driver configuration that utilizes both a positive and a negative voltage supply to offer enhanced performance for driving a power device, e.g., IGBT or MOSFET. The means for supplying both positive and negative voltages for the gate driver configuration is directly from an isolated power source. For example, the power may be from a standard switch-mode arrangement utilizing magnetic isolation on a multi-winding tap transformer. The gate driver of the present disclosure is still able to use a commercially available gate driver IC but has eliminated the need for using the IC in combination with a bootstrapping circuit to achieve desired performance. Moreover, the gate driver configuration of the present disclosure uses a commercially available IC in such a manner as to allow negative supply operation of the gate of the connected power device. By using the gate driver configuration of the present disclosure the componentry necessary for operation of the power device may be reduced and require less physical space. Further, the gate driver configuration of the present disclosure offers the usage of IC integrated protections and features without sacrificing other functionality.

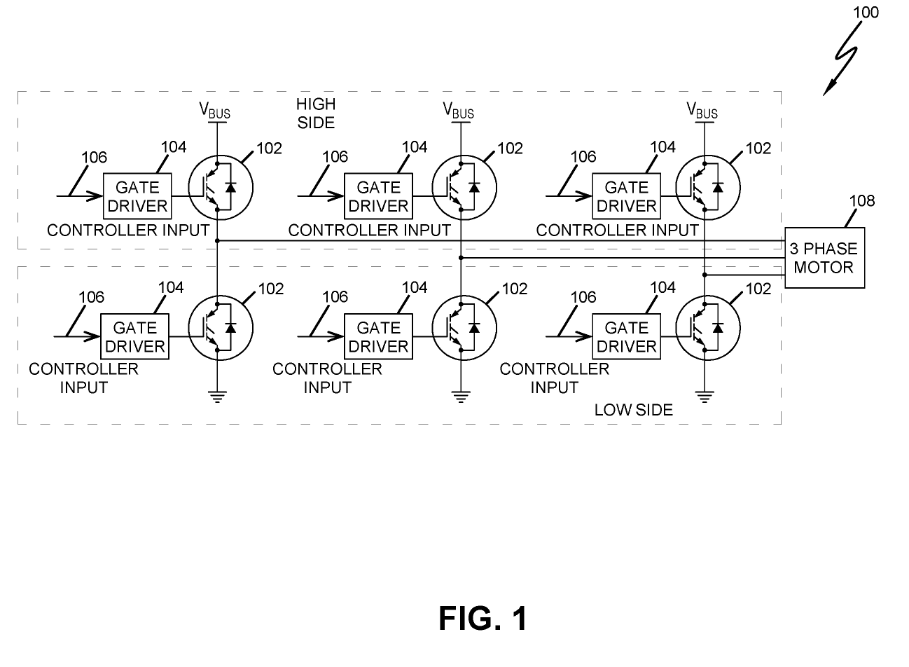

Referring now to FIG. 1, a typical gate driver circuit topology for a three-phase inverter connected to an electrical motor is shown. The typical gate driver arrangement 100 includes six power devices 102, e.g., IGBTs (used in this example; having a collector, gate, and emitter) or MOSFETs (having a drain, gate and source). Three of the power devices 102 are high side devices coupled to a high voltage DC bus while the other three of the power devices 102 are low side devices with their emitters coupled to ground. A local gate driver 104 drives the gate of each power device 102 and effectively isolates the high-voltage output of the power devices 102 from the low voltage control inputs 106. The power devices 102 are used in half-bridge configuration with each half-bridge coupled to one leg of a three-phase motor 108. The high-side and the low side power devices 102 are used to apply positive and negative high-voltage DC pulses, respectively, to the motor 108 in an alternating mode. Note, FIG. 1 depicts individual local gate drivers 104 for each power device 102 but other configurations are possible for multiple gate control outputs from a single device.

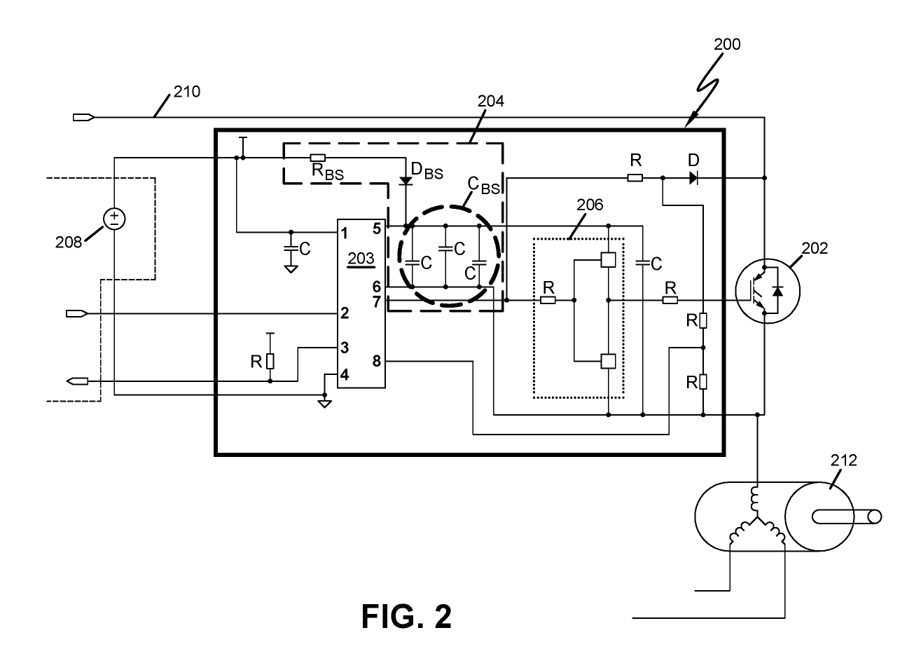

FIG. 2 provides further insight into the design of a typical local gate driver 200 for a high side power device 202. The local gate driver 200 operates to bias the power device 202 on and off in response to a control signal (for example, a pulse width modulation signal, not shown). As illustrated, the local gate driver 200 incorporates a commercially available gate driver IC 203, a bootstrap circuit 204 to supply power to the high side drive circuitry, and an optional pre-driver 206; a high DC bus voltage 210 is provided to the power device 202. An example of a commercially available gate driver IC is the IR 2127 available from International Rectifier. The IR 2127 is configured with built-in high voltage isolation. Other commercially available gate driver ICs may be used without departing from the scope of the disclosure. The local gate driver IC 203 is of an eight-pin configuration having the following pins (1) V_{SUP}—the logic and gate drive supply which is coupled to the positive side of the low voltage supply VSUPPLY 208; (2) CTRL IN—the logic input for the gate driver output (DRVOUT) which is coupled to the gate control signal from the controller (not shown); (3) DIAG OUT—a diagnostic output signal; (4) COMMON—ground; (5) BOOST—high side floating supply voltage; (6) ISO_COM—high side floating supply return; capacitor(s), C_{BS} is connected across BOOST and ISO_COM; (7) DRVOUT—high side gate drive output coupled to the gate of power device 202; and (8) SENSE—input to a comparator for representative power device current level. The emitter of the high side power 202 device is coupled to one leg of a three-phase motor 212.

The bootstrap circuit 204 of local gate driver 200 generally comprises bootstrap resistor R_{BS}, bootstrap diode D_{BS}, and bootstrap capacitor(s) C_{BS}. The pre-driver 206 may comprise, for example, a totem pole-style pre-drive circuit that can be used to minimize parasitic effects of the gate drive implementation. If the power devices cannot be substantially drive by the gate integrated circuit itself, a pre-drive circuit is needed.

The typical local gate driver 200 illustrated in FIG. 2 operates as follows. Presuming initial conditions of the high side power device 202 turned off and corresponding low side power device 202 (not shown in FIG. 2, see FIG. 1) turned on. The bootstrap capacitor, C_{BS}, is charged when the low side power device 202 is conducting and the emitter of the high side power device 202 is at a low potential. C_{BS} is charged from V_{SUP} through D_{BS}. Now, the direction of current through the bridge needs to change. The low side power device 202 (now shown, see FIG. 1) is turned off by driving the gate of the low side power device 202 low. The emitter of the high side power device 202 is no longer tied to ground and floats up relative to the connected supply 210. As a result, V_{E}>V_{SUP}. C_{BS} remains charged for the time being. Blocking diode D_{BS} provides high side isolations to the low voltage system/side and prevents it from discharging into V_{SUP}. Next, DRVOUT is powered by C_{BS} and the high side power device 202 is turned on by connecting the gate of the device to the charged C_{BS}. The gate capacitance of the high side power device 202 is charged from C_{BS} and the gate voltage goes up to turn on the high side power device 202. Finally, the high side power device 202 is turned off by connecting its gate to its emitter and the low side power device 202 (not shown, see FIG. 1) is turned on by driving its gate to V_{SUP}. The described cycle then repeats.

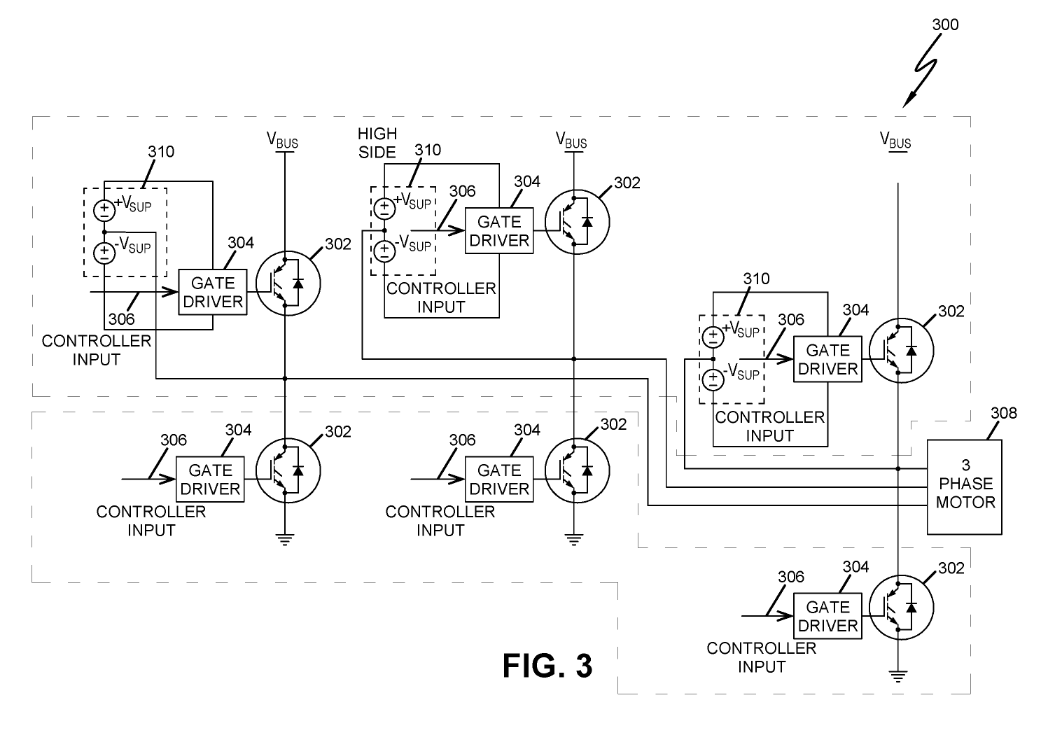

FIG. 3 illustrates a gate driver arrangement 300 for a three-phase inverter according to various embodiments of the present disclosure. As shown, the gate driver arrangement 300 includes six power devices 302, e.g., IGBTs (used in this example) or MOSFETs. Three of the power devices 302 are high side devices coupled to a high voltage DC bus while the other three of the power devices 302 are low side devices with their emitters coupled to ground. A local gate driver 304 drives the gate of each power device 302. The power devices 302 are used in a half-bridge configuration with each half-bridge coupled to one leg of a three-phase motor 308. The high-side and the low side power devices 302 are used to apply positive and negative high-voltage DC pulses, respectively, to the motor 308 in an alternating mode. Different from the gate driver arrangement 100 of FIG. 1 is the provision of an isolated voltage supply 310, with positive voltage supply, +Vsup, and negative voltage supply, −Vsup, for each of the high side gate drivers 304.

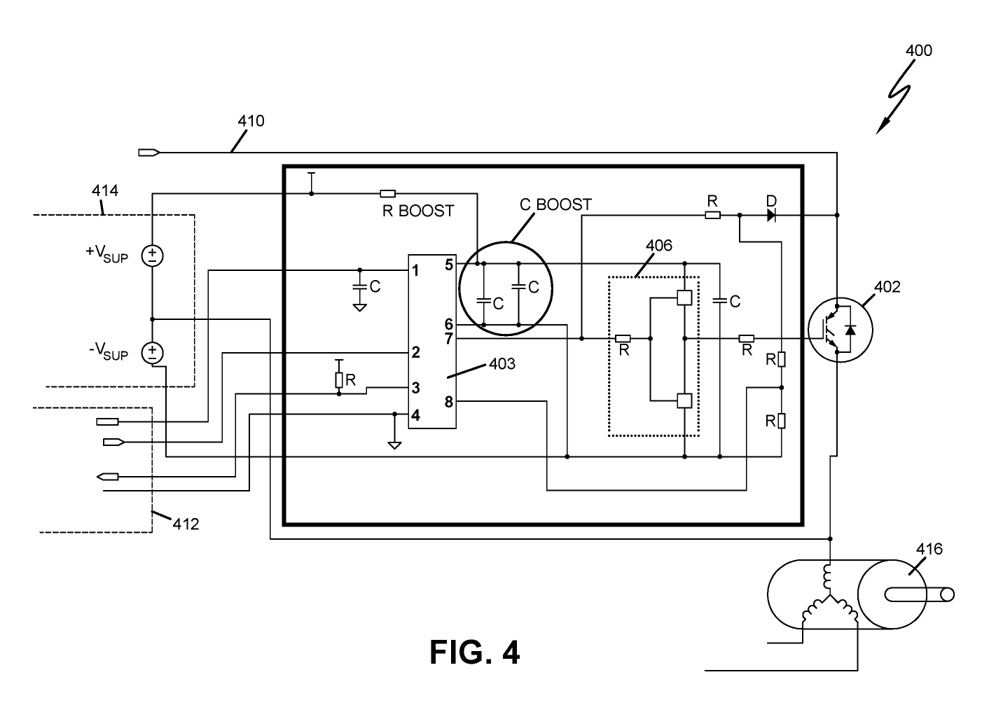

FIG. 4 provides further insight into the design of a local gate driver 400 for a high side power device 402 according to the various embodiments of the present disclosure. The local gate driver 400 operates to bias the power device 402 on and off in response to a control signal (for example, a pulse width modulation signal, not shown). As illustrated, the local gate driver 400 incorporates the same commercially available gate driver IC 403 as used in the gate driver 200 of FIG. 2 as well as an optional pre-driver 406, however, the bootstrap circuit of FIG. 2 has been eliminated while an isolated voltage supply 414 has been added. A high DC bus voltage 410 is provided to the power device 402 collector. A low voltage supply, common system 412 is provided to power the IC 403 while the isolated voltage supply 414, supplies both positive voltage, +Vsup, and negative voltage, −Vsup, to the gate of the power device 402. The common between +Vsup and −Vsup is tied to the emitter of the power device 402. Note that each high side gate driver 400 is preferably provided with its own, individual isolated voltage supply 414. All of low side gate drivers 400 may be powered by a single, positive/negative low voltage supply 412, or each may have their own, individual low voltage supplies.

The pins of the gate driver IC 403 are defined as follows: (1) V_{SUP}—the logic and gate drive supply which is coupled to the low voltage supply, common system 412; (2) CTRL IN—the logic input for the gate driver output (DRVOUT) which is coupled to the gate control signal from the controller (not shown); (3) DIAG OUT—a diagnostic output signal; (4) COMMON—ground from low voltage supply, common system 412; (5) BOOST—high side floating supply voltage coupled the positive voltage supply, +Vsup, of the isolated voltage supply 414; (6) VS— high side floating supply return tied to the negative voltage supply, −Vsup, of the isolated voltage supply 414; capacitor(s) C_{BOOST} is connected across BOOST and VS; (7) DRVOUT—high side gate drive output coupled to the gate of power device 402 (or to the optional pre-driver if used); and (8) SENSE—current sense input to current sense comparator. The emitter of the high side power 402 device is coupled to one leg of a three-phase motor 416.

The local gate driver 400 incorporating an isolated voltage supply 414 with positive voltage supply, +Vsup, and negative voltage supply, −Vsup, illustrated in FIG. 4 operates as follows. Presuming initial conditions of the high side power device 402 turned off and corresponding low side power device 402 (not shown in FIG. 4, see FIG. 3) turned on. The local capacitor, previously required in a bootstrapping configuration, C_{BOOST}, is charged when the low side power device is conducting and the emitter of the high side power device 402 is at a low potential. C_{BOOST} is optional and serves as near-by energy storage for the circuit configuration while being supplied by +Vsup of the isolated voltage supply 414. Next, the low side power device 402 (not shown, see FIG. 3) is turned off by driving the gate of the device low. With the low side power device off, the emitter floats relative to the external inverter supply 410 and the mid-point voltage of the isolated voltage supply 414. As a result, V_{E}>V_{SUP}. C_{BOOST} remains charged by the voltage supplied by +Vsup. Next, DRVOUT is powered by C_{BOOST} and the high side power device 402 is turned on by connecting the gate of the device to the charged C_{BOOST}. The gate capacitance of the high side power device 402 is charged from the optional C_{BOOST} capacitor(s) and the isolated voltage source 414, and the gate voltage goes up. Finally, the high side power device 402 is turned off by connecting its gate to its emitter and the low side power device 402 is turned on by driving its gate to −V_{SUP}.

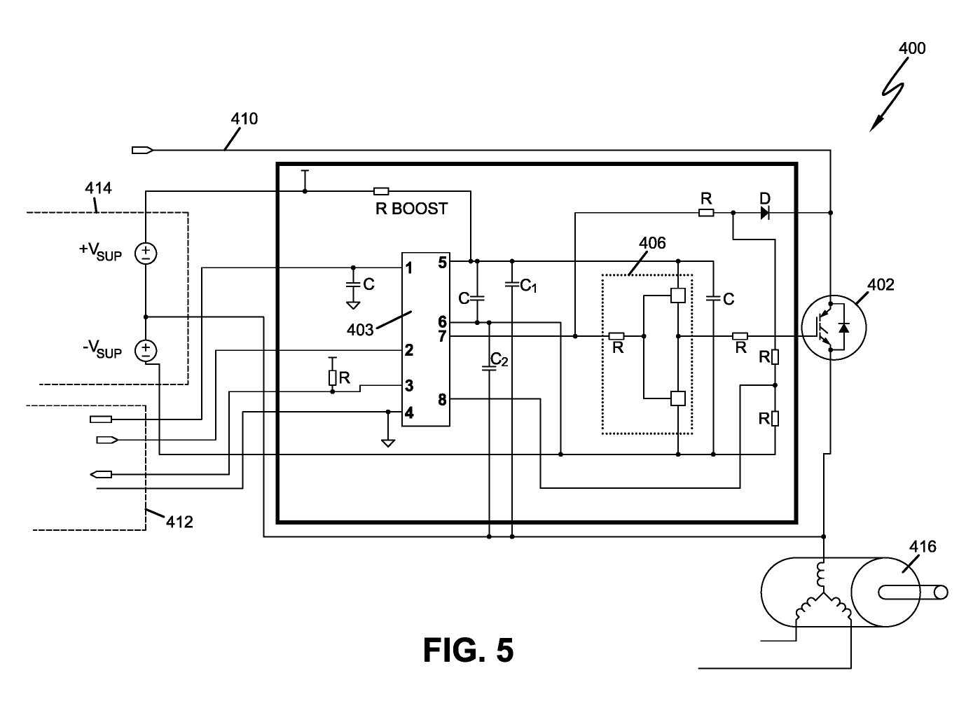

In another example embodiment, the local gate driver 400 of FIG. 4 is provided with an alternative capacitor arrangement as illustrated in FIG. 5. In this configuration, capacitor C remains across (5) BOOST and (6) VS, while capacitor C₁ is tied between (5) BOOST and the common of the isolated voltage supply 414 and capacitor C₂ is tied between (6) VS and the same common. Capacitors C₁ and C₂ provide optional local energy storage for the high-side driver 400 relative to the load and the common point of the isolated voltage supply.

The above-described, high side power device gate driver configuration features negative gate supply support with high voltage isolation and reduced components while retaining features and functionality of the gate driver IC. The negative gate supply support, which is unavailable in the typical gate driver, is particularly useful, for example, when a semiconductor manufacturer specifies negative gate bias for a power device, when the gate voltage cannot be held safely below the threshold voltage due to noise generated in the circuit, or when reduced power device turn-off energy loss characteristics are desired. Reduced components are achieved in that attempting a negative supply with the typical gate driver would generally require the use of an additional totem-pole driver between the power device gate and the boot-strapped gate driver IC; the high side power device gate driver configuration of the present disclosure eliminates the need for this totem-pole driver.

One example of retained features with the high side power device gate driver configuration of the present disclosure may be described with reference to the overcurrent/desaturation protection of the gate driver IC. In the typical gate driver configuration (bootstrapped configuration), the emitter of the power device is connected to the isolated side of the IC at the pin VSRETURN. However, if this connection is made but a negative supply is attempted, the overcurrent detection of the IC will not operate properly as the driver supply is connected to a negative reference but the overcurrent sense is referenced to the emitter of the power device, which is at ground. The result is that the current sense function of the gate driver IC will always register a faulted situation. Eliminating the bootstrapping circuit from the typical gate driver and incorporating the isolated positive and negative voltage supplies, as described earlier, maintains the functionality of the current sense function of the IC.

Systems, devices or methods disclosed herein may include one or more of the features structures, methods, or combination thereof described herein. For example, a device or method may be implemented to include one or more of the features and/or processes above. It is intended that such device or method need not include all of the features and/or processes described herein, but may be implemented to include selected features and/or processes that provide useful structures and/or functionality.

Various modifications and additions can be made to the disclosed embodiments discussed above. For example, the IGBT (collector, gate, emitter) used in the description of the disclosure may be replaced by a MOSFET (drain, gate, source). Accordingly, the scope of the present disclosure should not be limited by the particular embodiments described above, but should be defined only by the claims set forth below and equivalents thereof.

What is claimed:

1. A system comprising:
a power device having a gate, configured to turn on in response to a control voltage applied at the gate;
a gate driver integrated circuit electrically coupled to the gate and configured to supply the control voltage without use of a bootstrap circuit; and
an isolated voltage supply comprising a negative voltage supply electrically coupled to the gate.

2. The system of claim 1, wherein the isolated voltage supply further comprises a positive voltage supply electrically coupled to the negative voltage supply and electrically coupled to the gate.

3. The system of claim 2, wherein the positive voltage supply is configured to charge a capacitor to generate the control voltage.

4. The system of claim 2, wherein a common between the positive and negative voltage supplies is electrically coupled to a power termination of the power device.

5. The system of claim 1, wherein the gate driver integrated circuit incorporates overcurrent/desaturation protection.

6. The system of claim 4, wherein the gate driver integrated circuit is referenced to the negative voltage supply enabling operation of the overcurrent/desaturation protection.

7. The system of claim 1, further comprising a low voltage supply electrically coupled to the gate driver integrated circuit and configured to power the gate driver integrated circuit.

8. A system comprising:
a three-phase power inverter having three high side power devices and three low side power devices, each high side power device coupled to a respective one of the low side power devices in a half-bridge configuration, wherein each high side power device is electrically coupled to a gate driver integrated circuit, the gate driver integrated circuit referenced to a negative voltage provided by an isolated negative voltage supply and the gate driver integrated circuit configured to produce a control voltage sufficient to turn on the power device without the use of a bootstrap circuit.

9. The system of claim 8, wherein the isolated voltage supply further comprises a positive voltage supply electrically coupled to the negative voltage supply.

10. The system of claim 9, wherein both the positive and negative voltage supplies are coupled to a gate of the high side power device.

11. The system of claim 9, wherein a common between the positive and negative voltage supplies is electrically coupled to a power termination of the power device.

12. The system of claim 9, wherein the positive voltage supply is configured to charge a capacitor to generate the control voltage.

13. The system of claim 8, further comprising a low voltage supply electrically coupled to each of the gate driver integrated circuits of each of the high side power devices, the low voltage supply configured to power the gate driver integrated circuits.

14. The system of claim 8, wherein the gate driver integrated circuit incorporates overcurrent/desaturation protection which is enabled by the gate driver integrated circuit being referenced to the isolated negative voltage supply.

15. A method comprising:
charging a capacitor with an isolated high voltage, positive voltage supply to generate a first voltage;
providing the first voltage to a gate driver integrated circuit that is referenced to a negative voltage supplied by an isolated negative voltage supply;
using the gate driver integrated circuit to generate a control voltage from the first voltage; and
applying the control voltage to a gate of a power device to turn on the power device.

16. The method of claim 15, wherein the isolated positive voltage is coupled to the isolated negative voltage.

17. The method of claim 15, wherein the both the isolated positive and negative voltage are coupled to the gate of the power device.

18. The method of claim 15, further comprising powering the gate driver integrated circuit with a low voltage supply.

19. The method of claim 15, electrically coupling a common between the isolated positive and negative voltage supplies to a power termination of the power device.

20. The method of claim 15, wherein charging of the capacitor occurs without use of a bootstrap circuit.
